(19) United States
(12) Patent Application Publication
(10) Pub. No.: US 2011/0063903 A1
(43) Pub. Date: Mar. 17, 2011

(54) NONVOLATILE MEMORY DEVICES, SYSTEMS HAVING THE SAME, AND WRITE CURRENT CONTROL METHODS THEREOF

(75) Inventors: Yong Hoon Kang, Seoul (KR); Dongyang Lee, Yongin-si (KR)

(73) Assignee: SAMSUNG ELECTRONICS CO., LTD., Suwon-si (KR)

(21) Appl. No.: 12/832,200

(22) Filed: Jul. 8, 2010

(30) Foreign Application Priority Data
Sep. 15, 2009 (KR) 10-2009-0087062

(51) Int. Cl. G11C 11/00; G06F 12/00

(52) U.S. Cl. 365/163; 711/102; 365/148

(57) ABSTRACT

Provided is a nonvolatile memory device, a memory system having the same, and a write current control method thereof. The memory system includes a nonvolatile memory device and a memory controller. The nonvolatile memory device has a plurality of write modes. The memory controller includes a sensor configured to sense environment information of the memory system. The memory controller is configured to select one of the write modes according to the sensed environment information and control the nonvolatile memory device according to the selected write mode. Accordingly, the nonvolatile memory device provides a write current for appropriate current consumption in a write operation.

### CROSS-REFERENCE TO RELATED APPLICATIONS

This U.S. non-provisional patent application claims priority under 35 U.S.C. §119 to Korean Patent Application No. 10-2009-0087062, filed on Sep. 15, 2009, the entire contents of which are hereby incorporated by reference.

### BACKGROUND

The present disclosure herein relates to nonvolatile memory devices, and more particularly, to nonvolatile memory devices, systems having the same, and write current control methods thereof.

Semiconductor memory devices are microelectronic devices that are used to design digital logic circuits such as microprocessor-based applications and computers for the fields ranging from satellite to consumer electronics. Therefore, an advance in memory fabrication technology, including technology development and process improvement obtained through scaling for high speed and high integration density, assists in establishing the performance standards of other digital logic systems.

Semiconductor memory devices are generally classified into volatile memory devices and nonvolatile memory devices. The nonvolatile memory devices can retain data stored therein even when power supply thereto is interrupted. Data stored in the nonvolatile memory devices may be permanent or reprogrammable according to memory fabrication technologies. The nonvolatile memory devices are used to store programs and microcodes in various applications such as computers, avionics, communications, and consumer electronic technologies.

### SUMMARY

Example embodiments of inventive concepts provide nonvolatile memory devices, systems having the same, and write current control methods thereof.

In some example embodiments of inventive concepts, memory systems include a nonvolatile memory device driven having a plurality of write modes, and a memory controller including a sensor configured to sense system environment information, the memory controller being configured to select one of the plurality of write modes according to the sensed system environment information, and control the nonvolatile memory device according to the selected write mode.

In some example embodiments, the nonvolatile memory device is configured to apply at least one of a number of set pulses associated with one of the write modes and a number of reset pulses associated with the one of the write modes in a write operation.

In other example embodiments, the nonvolatile memory device includes a mode circuit configured to set one of the write modes.

In further example embodiments, the memory controller is configured to provide a high voltage to a high-voltage pad of the nonvolatile memory device in a write operation, the sensor is configured to sense if the level of the high voltage provided to the high-voltage pad decreases as the system environment information.

In still further example embodiments, the system environment information includes at least one of temperature, current capacity, high-voltage level, and battery capacity.

In still further example embodiments, if the system environment information is current capacity, the sensor is configured to sense the current capacities used by the memory system and the memory controller is configured to select one of the write modes according to the sensed current capacities.

In still further example embodiments, the nonvolatile memory device is a phase-change memory device.

In still further example embodiments, the peak current value of the nonvolatile memory device varies according to the selected write mode.

In other example embodiments of inventive concepts, methods of controlling write currents of a nonvolatile memory device include estimating a current consumption, setting a write mode according to the estimated current consumption, and controlling the amount of simultaneously-provided write currents in a write operation according to the set write mode.

In some example embodiments, the estimating estimates the current consumption of the nonvolatile memory device according to the application of the nonvolatile memory device.

In other example embodiments, the current consumption estimation operation is performed in the nonvolatile memory device.

In further example embodiments, the current consumption estimation operation is performed in a system having the nonvolatile memory device.

In still further example embodiments, the setting sets the write mode from a plurality of modes and each of the modes corresponds to a number of enabled write drivers.

In still further example embodiments, the setting sets the write mode from a plurality of modes and each of the modes corresponds to at least one of a number of set pulses and a number of reset pulses.

In further example embodiments of inventive concepts, nonvolatile memory devices include a memory cell array including a plurality of variable-resistance cells; a write driver circuit configured to provide write currents to the variable-resistance cells selected in response to received set pulses or received reset pulses, and a control logic configured to generate the set pulses or the reset pulses in the write operation and determine at least one of a number of the reset pulses and a number of the set pulses according to the set write mode.

In some example embodiments, the write driver circuit is configured to receive a high voltage from an external device in a write operation.

In other example embodiments, the control logic includes a mode circuit configured to set a write mode according to estimated current consumption.

In further example embodiments, the nonvolatile memory device further includes a sensor configured to sense the current consumption.

In still further example embodiments, the mode circuit is configured to set the write mode setting operation is performed by fuse cutting.

In still further example embodiments, the mode circuit is configured to set the write mode by register setting.

### BRIEF DESCRIPTION OF THE DRAWINGS

The accompanying drawings are included to provide a further understanding of inventive concepts, and are incorporated in and constitute a part of this specification. The drawings illustrate example embodiments of inventive concepts and, together with the description, serve to explain principles of inventive concepts. In the drawings:

FIG. 1 is a diagram illustrating a write current control method of a nonvolatile memory device according to an example embodiment of inventive concepts;

FIG. 2 is a block diagram of a nonvolatile memory device according to an example embodiment of inventive concepts;

FIG. 3 is a diagram illustrating pulses generated by a control logic according to inventive concepts;

FIG. 4 is a table illustrating an example embodiment of write modes of a nonvolatile memory device according to inventive concepts;

FIG. 5 is a block diagram illustrating a write operation of the nonvolatile memory device of FIG. 2;

FIG. 6 is a diagram illustrating a first write driver WD1 according to an example embodiment of inventive concepts;

FIG. 7 is a diagram illustrating a control method for a first mode of set pulses or reset pulses according to the table of FIG. 4;

FIG. 8 is a diagram illustrating a control method for a second mode of set pulses or reset pulses according to the table of FIG. 4;

FIG. 9 is a diagram illustrating a control method for a third mode of set pulses or reset pulses according to the table of FIG. 4;

FIG. 10 is a diagram illustrating a control method for a fourth mode of set pulses or reset pulses according to the table of FIG. 4;

FIG. 11 is a diagram illustrating a control method for a fifth mode of set pulses or reset pulses according to the table of FIG. 4;

FIG. 12 is a diagram illustrating a control method for a sixth mode of set pulses or reset pulses according to the table of FIG. 4;

FIG. 13 is a diagram illustrating a control method for a seventh mode of set pulses or reset pulses according to the table of FIG. 4;

FIG. 14 is a block diagram illustrating a read operation of the nonvolatile memory device of FIG. 2;

FIG. 15 is a block diagram of a nonvolatile memory device according to another example embodiment of inventive concepts;

FIG. 16 is a block diagram of a memory system according to an example embodiment of inventive concepts;

FIG. 17 is a block diagram of an integrated circuit (IC) according to an example embodiment of inventive concepts;

FIG. 18 is a diagram illustrating a method of setting a write mode according to the current capacity provided to a PRAM from the IC illustrated in FIG. 17;

FIG. 19 is a diagram illustrating a peak current corresponding to each mode of a nonvolatile memory device according to an example embodiment of inventive concepts;

FIG. 20 is a block diagram of a memory module according to an example embodiment of inventive concepts;

FIG. 21 is a block diagram of a memory system according to another example embodiment of inventive concepts; and

FIG. 22 is a block diagram of a computing system according to an example embodiment of inventive concepts.

### DETAILED DESCRIPTION OF EXAMPLE EMBODIMENTS

Example embodiments of inventive concepts will be described below in more detail with reference to the accompanying drawings. Inventive concepts may, however, be embodied in different forms and should not be construed as limited to example embodiments set forth herein. Rather, these example embodiments are provided so that this disclosure will be thorough and complete, and will fully convey the scope of inventive concepts to those skilled in the art.

It will be understood that, although the terms first, second, third etc. may be used herein to describe various elements, these elements should not be limited by these terms. These terms are used to distinguish one element from another. Thus, a first element discussed below could be termed a second element without departing from the teachings of inventive concepts.

It will be understood that when an element, such as a layer, a region, or a substrate, is referred to as being “on,” “connected to” or “coupled to” another element, it may be directly on, connected or coupled to the other element or intervening elements may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

The terminology used herein is for the purpose of describing particular example embodiments only and is not intended to be limiting of inventive concepts. As used herein, the singular forms “a,” “an” and “the” are intended to include the plural forms as well, unless the context clearly indicates otherwise. It will be further understood that the terms “comprises”, “comprising”, “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

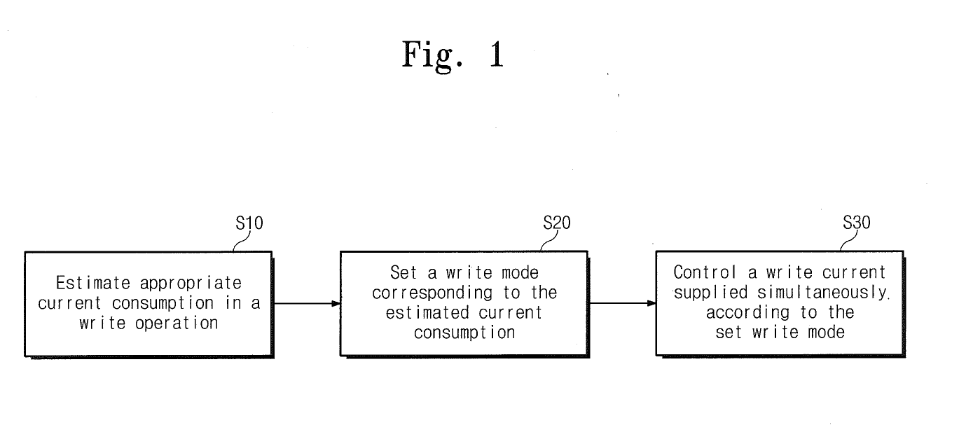

FIG. 1 is a diagram illustrating a write current control method of a nonvolatile memory device according to an example embodiment of inventive concepts.

Referring to FIG. 1, a write current control method of a nonvolatile memory device is performed as follows.

Appropriate current consumption is estimated in a write operation (S10). Herein, the appropriate current consumption is the current consumption of the nonvolatile memory device that is to provide improved performance on the system level. For example, if the current consumption of other devices in the system is high, the current consumption of the nonvolatile memory device is estimated so that a relatively small current is consumed in the nonvolatile memory device. On the other hand, if the current consumption of other devices in the system is low, the current consumption of the nonvolatile memory device is estimated so that a relatively large current is consumed in the nonvolatile memory device.

Also, if the current supply to the nonvolatile memory device is not smooth according to system environment information, the current consumption of the nonvolatile memory device is estimated so that a relatively small current is consumed in the nonvolatile memory device. Herein, the system environment information may be temperature, noise, battery power, or current capacity of a power source. On the other hand, if the current supply to the nonvolatile memory device is smooth according to system environment information, the current consumption of the nonvolatile memory device is estimated so that a relatively large current is consumed in the nonvolatile memory device.

Appropriate current consumption estimation is performed by a manufacturer or the nonvolatile memory device, by a designer of a memory system having the nonvolatile memory device, or by a specific device inside or outside the nonvolatile memory device.

A write mode of the nonvolatile memory device is set according to the estimated appropriate current assumption (S20). Herein, the nonvolatile memory device is driven according to one of a plurality of write modes. The write modes are implemented variously in the nonvolatile memory device.

In example embodiments, a manufacturer, a nonvolatile memory device corresponding to each mode, or a designer of a memory system having the nonvolatile memory device selects a write mode according to the estimated appropriate current consumption and performs a physical connection operation to set the selected write mode. For example, the physical connection operation may be fuse cutting.

In another example embodiment, a data value corresponding to each mode is present, a manufacturer, the nonvolatile memory device, or a designer of a memory system having the nonvolatile memory device or a specific device located inside or outside the nonvolatile memory device selects a write mode according to the estimated appropriate current consumption and performs a data setting operation to set the selected write mode. For example, the physical connection operation may be fuse cutting. For example, the data setting operation may be a register setting operation. The register setting operation may be performed by reading data of a specific region in the nonvolatile memory device or by receiving data from an external device.

After the write mode is set, the nonvolatile memory device controls a write current provided simultaneously according to the selected write mode in a write operation. Herein, the simultaneously-provided write current is controlled by controlling the number of simultaneously-applied set pulses or the number of simultaneously-applied reset pulses. Herein, the set pulses are used for a set operation in the write operation and the reset pulses are used for a reset operation in the write operation. The current consumption in the write operation varies according to the number of reset pulses or set pulses applied. In other words, the current consumption in the write operation varies according to the write mode.

The nonvolatile memory device according to inventive concepts estimates appropriate current consumption and sets a write mode corresponding to the estimated current consumption. Accordingly, the nonvolatile memory device performs a write operation such that an appropriate current is consumed in the write operation. Consequently, the overall operation of the system having the nonvolatile memory device improves.

For convenience in description, it is assumed below that the nonvolatile memory device is a phase-change memory device (e.g., a Phase-change Random Access Memory (PRAM) device). However, the nonvolatile memory device of inventive concepts is not limited to a phase-change memory device. Examples of the nonvolatile memory device of inventive concepts include NOR flash memory devices, Resistive Random Access Memory (RRAM) devices, Magnetoresistive Random Access Memory (MRAM) devices, Ferroelectric Random Access Memory (FRAM) devices, and Spin Transfer Torque Random Access Memory (STT-RAM) devices.

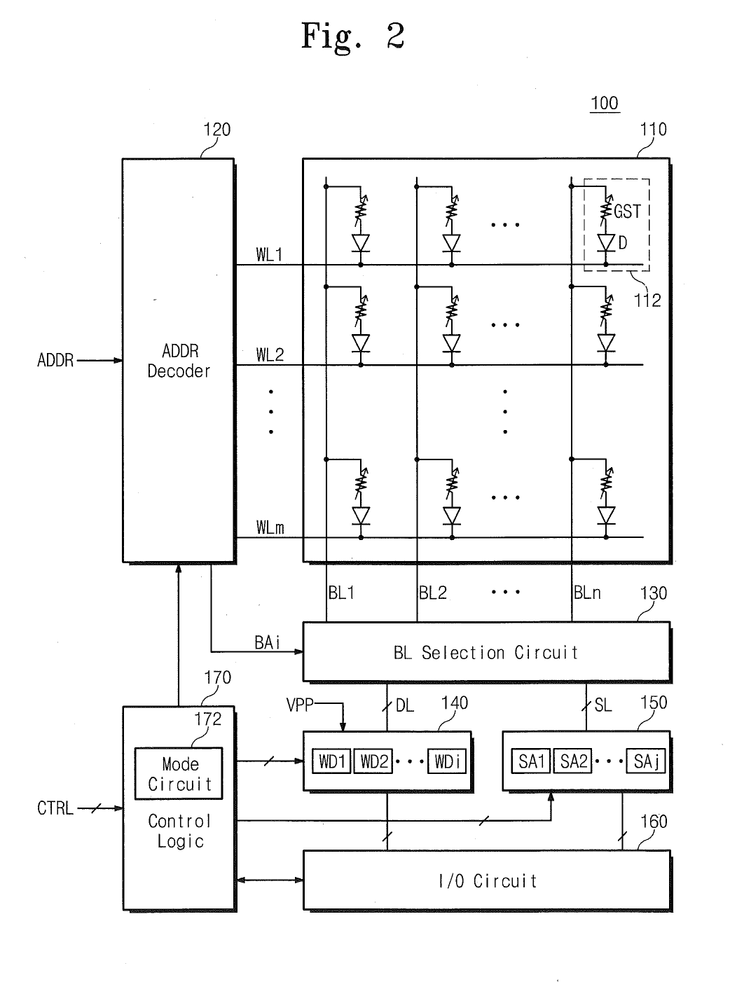

FIG. 2 is a block diagram of a nonvolatile memory device according to an example embodiment of inventive concepts.

Referring to FIG. 2, a nonvolatile memory device 100 includes a memory cell array 110, an address decoder 120, a bit line (BL) selection circuit 130, a write driver circuit 140, a sense amplifier (SA) circuit 150, an input/output (I/O) circuit 160, and a control logic 170.

The memory cell array 110 includes memory blocks (not illustrated). Each of the memory blocks includes memory cells disposed at the intersections of word lines WL1-WLm and bit lines BL1-BLn. Herein, “m” and “n” are natural numbers. Each of the memory cells includes a resistance element and a switching element.

The resistance element includes a phase-change layer formed of a chalcogenide material. Herein, the chalcogenide material is a germanium (Ge)-antimony (Sb)-tellurium (Te) compound (hereinafter referred to as a GST). However, the chalcogenide material of e inventive concepts is not limited to a GST. The chalcogenide material of inventive concepts is a compound that is thermally stabilized and can rapidly change into a crystalline state or an amorphous state.

The chalcogenide material an amorphous state (i.e., a reset state) with relatively high resistivity and a crystalline state (i.e., a set state) with relative low resistivity.

The phase-change layer changes into a crystalline state or an amorphous state according to the temperature applied thereto. The temperature of the phase-change layer may be changed by laser beams or by Joule heat that is generated by applying a current to a heater. In applying a current to the heater, the heating time and the temperature of the heater may vary according to the current applying time and the amount of a current applied to the heater. These characteristics are used to determine a crystalline state of an amorphous state of the phase-change layer.

For example, when heated with a relatively large amount of current for a short time, the phase-change layer has an amorphous state. On the other hand, when heated with a relatively small amount of current for a long time, the phase-change layer has a crystalline state. The resistance value of the phase-change layer changes according to the state of the phase-change layer. For example, the phase-change layer with a crystalline state has a low resistance value and the phase-change layer with an amorphous state has a high resistance value.

A data state is determined according to the state of the resistance value. For example, the high resistance value corresponds to ‘0’ and the low resistance value corresponds to ‘1’. In summary, a write operation determines the state of a phase-change layer and a read operation senses the resistance value of a phase-change layer.

The switching element may be implemented using various elements such as MOS transistors and diodes. Each memory cell 112 stores N-bit data information (N: a natural number). Also, each memory cell 112 is an overwrite memory cell.

The address decoder 120 is configured to decode an address ADDR received from an external device. Herein, the address ADDR include a row address RA and a column address CA. The address decoder 120 selects one of the word lines WL1-WLm according to the row address RA. Also, the address decoder 120 decodes the column address CA and provides a bit line selection signal BAi to the bit line selection circuit 130 according to the decoding result.

The bit line selection circuit 130 is connected through the bit lines BL1-BLn to the memory cell array 110, is connected through data lines DL to the write driver circuit 140, and is connected through sensing lines SL to the sense amplifier circuit 150. The bit line selection circuit 130 selects a predetermined number of bit lines among the bit lines BL1-BLn in response to the bit line selection signal BAi. According to the selection result, the data lines DL or the sensing lines SL are electrically connected to the selected bit lines.

The write driver circuit 140 receives write pulses (e.g., set pulses or reset pulses) from the control logic 170, receives data from the input/output circuit 160, and provides write currents (e.g., set currents or reset currents) to the data lines DL. The write driver circuit 140 includes write drivers WD1-WDi. Herein, “i” is a natural number. Each of the write drivers WD1-WDi generates a set current in response to a set pulse when receiving data ‘0’, and generates a reset current in response to a reset pulse when receiving data ‘1’. Herein, the data ‘0’ corresponds to the crystalline sate of a chalcogenide material and the data ‘1’ corresponds to the amorphous state of a chalcogenide material.

The write driver circuit 140 receives a write current through a high voltage VPP in a write operation. Herein, the high voltage VPP may be generated by an internal voltage generator (not illustrated) of the nonvolatile memory device 100 or may be provided from an external device of the nonvolatile memory device.

The sense amplifier circuit 150 provides a read current (or a bias current) to the memory cell array 110 through the sensing lines SL in a read operation. In the read operation, the sense amplifier circuit 150 compares the voltage of the sensing lines SL with a reference voltage to read data stored in the memory cell. Herein, the reference voltage may be provided from a reference voltage generator circuit (not illustrated). In the read operation, the voltages of the sensing lines SL may vary according to the resistance values of the corresponding memory cells. The sense amplifier circuit 150 includes sense amplifiers SA1-SAj. Herein, “j” is a natural number.

The input/output circuit 160 stores data inputted from an external device in a write operation, or stores data sensed from the sense amplifier circuit 150 in a read operation. In the write operation, the inputted data are provided to the respective write drivers WD1-WDi under the control of the control logic 170. In the read operation, the read data are outputted from the respective sense amplifier SA1-SAj to an external device under the control of the control logic 170.

The control logic 170 controls the address decoder 120, the write driver circuit 140, the sensor amplifier circuit 150 and the input/output circuit 160 in response to control signals CTRL. For example, the control logic 170 provides the write driver circuit 140 with a write pulse (e.g., a set pulse or a reset pulse) for generation of write currents in a write operation. Also, the control logic 170 provides the sense amplifier circuit 150 with a read pulse (e.g., a bias signal) for generation of a read current in a read operation.

The control logic 170 includes a mode circuit 172 for setting a write mode. The mode circuit 172 is configured to set one of a plurality of modes. The mode circuit 172 is implemented to set a write mode by a mode register set or to set a write mode by fuse cutting. Herein, information related to the modes may be stored in the nonvolatile memory device 100 or may be received from an external device (e.g., a memory controller).

Herein, the write mode setting operation of the mode circuit 172 may be performed by a manufacture of the nonvolatile memory device 100 or by a designer of a memory system having the nonvolatile memory device 100.

For example, if the nonvolatile memory device is to be used in a system of low current consumption (e.g., a portable terminal), a manufacturer of the nonvolatile memory device (or a designer of the system) sets a write mode of the mode circuit 172 so that a relatively small current is consumed in the nonvolatile memory device. On the other hand, if the nonvolatile memory device is to be used in a system of high current consumption, a manufacturer of the nonvolatile memory device (or a designer of the system) sets a write mode of the mode circuit 172 so that a relatively large current is consumed in the nonvolatile memory device.

In the nonvolatile memory device 100 of inventive concepts, a write mode of the mode circuit 172 may be set so that various currents may be consumed according to the write mode set in a write operation. Consequently, a write mode of the nonvolatile memory device 100 may be set so that an appropriate current may be consumed on the system level.

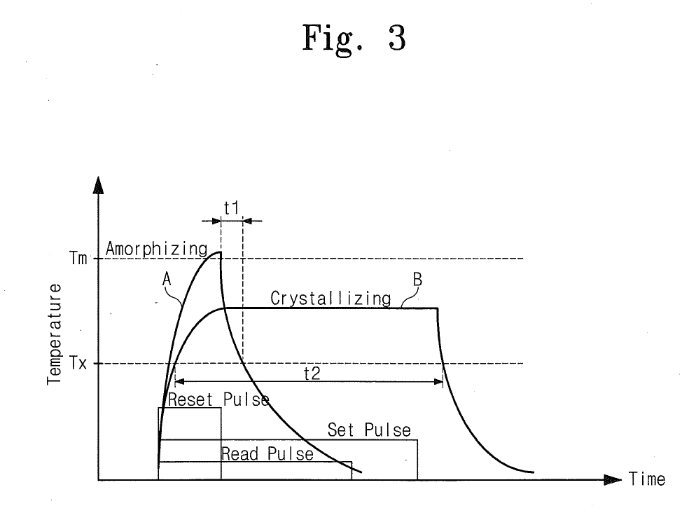

FIG. 3 is a diagram illustrating pulses generated by the control logic 170 according to inventive concepts.

Referring to FIG. 3, a curve A represents a temperature change of the phase-change layer according to the application of a reset pulse, and a curve B represents a temperature change of the phase-change layer according to the application of a set pulse. A temperature Tm is a melting temperature of the phase-change layer, and a temperature Tx is a crystallization temperature of the phase-change layer.

A reset pulse is generated so that the phase-change layer is rapidly cooled within a predetermined time t1 after being heated to a temperature higher than the melting temperature Tm. The reset pulse causes the phase-change layer to become an amorphous state.

A set pulse is generated so that the phase-change layer is cooled after a predetermined time t2 after being heated to a temperature that is lower than the melting temperature Tm and is higher than the crystallization temperature Tx. Herein, the time t2 is longer than the time t1. The set pulse causes the phase-change layer to become a crystalline state.

A read pulse is generated during a time when the phase-change layer is heated to a low temperature not affecting the state change and can perform a sufficient sensing operation.

Because the melting temperature Tm is higher than the crystallization temperature Tx, a set current generated in response to the reset pulse is larger than a reset current generated in response to the set pulse. Therefore, the voltage level of the reset pulse may be higher than the voltage level of the set pulse. However, the voltage level of the reset pulse and the voltage level of the set pulse according to inventive concepts are not limited thereto. In the nonvolatile memory device 100 according to inventive concepts, the voltage level of the reset pulse may be equal to the voltage level of the set pulse.

The current consumption of the nonvolatile memory device 100 in a write operation depends on the number of simultaneously-enabled write drivers. In particular, the current consumption of the nonvolatile memory device 100 in a write operation depends on the number of simultaneously-applied reset pulses. This is because the reset current generated by the reset pulse is larger than the set current generated by the set pulse.

According to an example embodiment, the nonvolatile memory device 100 varies the amount of simultaneously-provided current according to the number of simultaneously-enabled write drivers or the number of simultaneously-applied reset pulses.

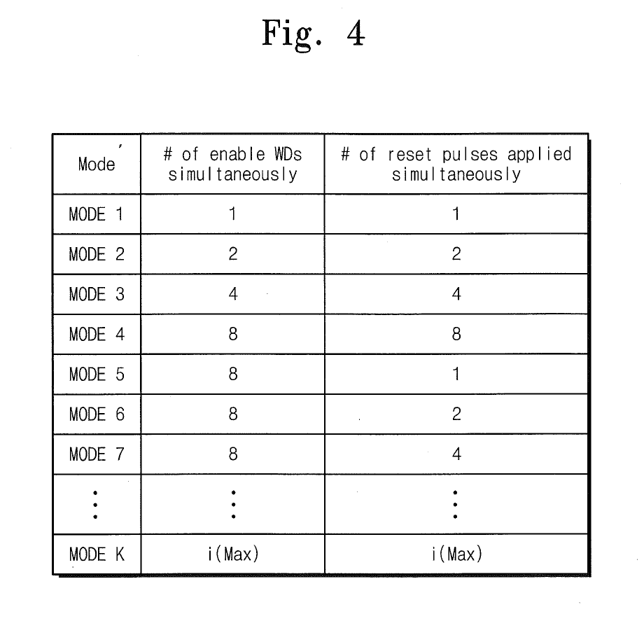

FIG. 4 is a table illustrating an example embodiment of write modes of the nonvolatile memory device according to inventive concepts.

Referring to FIG. 4, write modes are classified according to the number of simultaneously-enabled write drivers and the number of simultaneously-applied reset pulses.

For example, in the first mode, the number of simultaneously-enabled write drivers is 1 and the number of simultaneously-applied reset pulses is also 1. In the second mode, the number of simultaneously-enabled write drivers is 2 and the number of simultaneously-applied reset pulses is also 2. In the third mode, the number of simultaneously-enabled write drivers is 3 and the number of simultaneously-applied reset pulses is also 3. In the fourth mode, the number of simultaneously-enabled write drivers is 8 and the number of simultaneously-applied reset pulses is also 8. In the fifth mode, the number of simultaneously-enabled write drivers is 8 and the number of simultaneously-applied reset pulses is 1. In the sixth mode, the number of simultaneously-enabled write drivers is 8 and the number of simultaneously-applied reset pulses is 2. In the seventh mode, the number of simultaneously-enabled write drivers is 8 and the number of simultaneously-applied reset pulses is 4.

As described above, a write mode is determined according to various combinations of the number of simultaneously-enabled write drivers and the number of simultaneously-applied reset pulses.

In the nonvolatile memory device 100 according to inventive concepts, the current consumption in a write operation varies according to each write mode. For example, the smallest current is consumed in the first mode. On the other hand, the largest current is consumed in the K^{th} mode because all the write drivers (see FIG. 2; “i” is the maximum number of write drivers) are enabled. Thus, the write mode may be determined according to appropriate current consumption estimated by the manufacturer.

For convenience in description, it is assumed below that the write driver circuit 140 of FIG. 2 includes 8 write drivers. However, the write driver circuit of inventive concepts is not limited thereto.

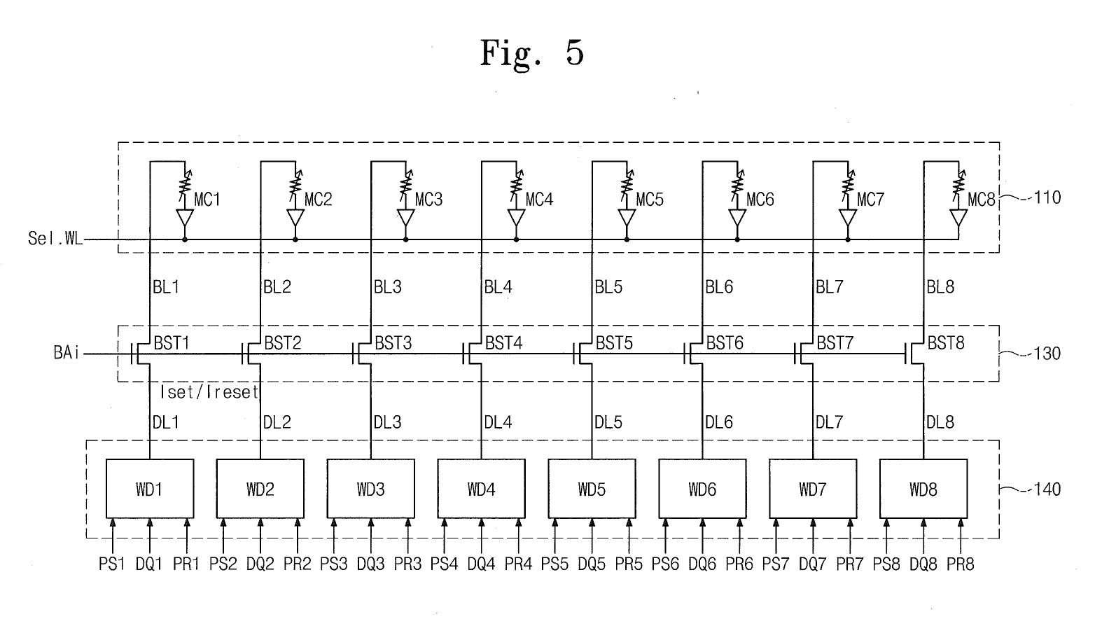

FIG. 5 is a block diagram illustrating a write operation of the nonvolatile memory device of FIG. 2.

Referring to FIG. 5, memory cells MC1-MC8 are connected to a selected word line Sel. WL.

The bit line selection circuit 130 is connected between bit lines BL1-BL8 and data lines DL1-DL8. The bit line selection circuit 130 electrically connects the data lines DL1-DL8 and the selected bit lines BL1-BL8 among the bit lines BL1-BLn in response to a bit line selection signal BAi. The bit line selection circuit 130 includes a plurality of units (not illustrated). Each of the units is enabled in response to the bit line selection signal BAi. For convenience in description, FIG. 5 illustrates only one select unit. Each of the units includes a plurality of NMOS transistors.

The write driver circuit 140 receives write pulses PS1-PS8, reset pulses PR1-PR8 and input data DQ1-DQ8, and provides corresponding write currents Iset and Ireset to the respective data lines DL1-DL8.

The write driver circuit 140 includes a plurality of write drivers WD1-WD8. Each of the write drivers WD1-WD8 provides one of the write currents Iset and Ireset to the selected memory cells.

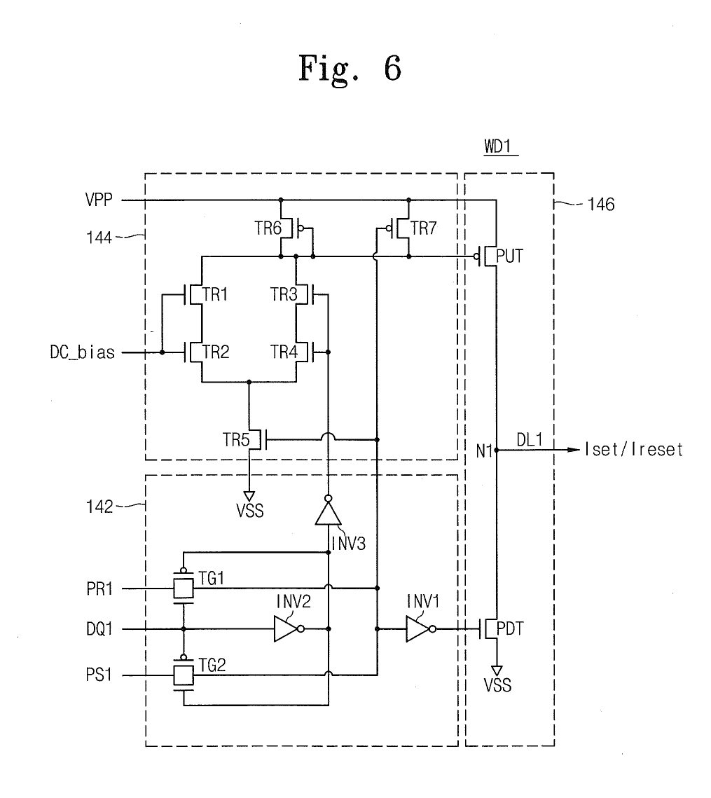

FIG. 6 is a diagram illustrating the first write driver WD1 according to an example embodiment of inventive concepts.

Referring to FIG. 6, the first write driver WD1 includes a pulse control circuit 142, a current control circuit 144, and a current driver circuit 146. However, the write driver of inventive concepts is not limited thereto.

The pulse control circuit 142 includes first and second transmission gates TG1 and TG2 and first to third inverters INV1-INV3. The current control circuit 144 includes first to seventh transistors TR1-TR7. Herein, the first to fifth transistors TR1-TR5 are NMOS transistors, and the sixth and seventh transistors are PMOS transistors. The current driver circuit 146 includes a pull-up transistor PUT and a pull-down transistor PDT.

An operation of the first write driver WD1 is described below.

First, a description is given of the case where the input data DQ1 is ‘0’. When the input data DQ1 is ‘0’, the second transmission gate TG2 of the pulse control circuit 142 is turned on and the third and fourth transistors TR3 and TR4 of the current control circuit 144 are turned off. Also, by the set pulse PS1, the fifth transistor TR5 is turned on and the seventh transistor TR7 and the pull-down transistor PDT are turned off. At this point, by the current mirror effect, a current flowing through the transistors TR1, TR2, TR5 and TR6 forming a first current path flows through the pull-up transistor PUT. The current flowing through the pull-up transistor PUT is a set current Iset, which is provided through the data line DL1 to the selected memory cell.

Second, a description is given of the case where the input data DQ1 is T. When the input data DQ1 is ‘1’, the first transmission gate TG1 of the pulse control circuit 142 and the third and fourth transistors TR3 and TR4 of the current control circuit 144 are turned on. Also, by the reset pulse PR1, the fifth transistor TR5 is turned on and the seventh transistor TR7 and the pull-down transistor PDT are turned off. At this point, by the current mirror effect, a current flowing through the transistors TR1, TR2, TR5 and TR6 forming a first current path flows through the pull-up transistor PUT. The current flowing through the pull-up transistor PUT is a reset current Ireset, which is provided through the data line DL1 to the selected memory cell.

Herein, the reset current Ireset has a greater current value than the set current Iset. Also, the reset pulse PR1 has a smaller pulse width than the set pulse PS1. This is because the phase-change layer must be rapidly cooled from a temperature higher than the melting temperature Tm so that it becomes an amorphous state.

The selected memory cell is written by the reset current Ireset or the set current Iset. For example, in the memory cell provided with the reset current Ireset, the phase-change layer becomes an amorphous state (i.e., a reset state). On the other hand, in the memory cell provided with the set current Iset, the phase-change layer becomes a crystalline state (i.e., a set state).

Meanwhile, the second to eighth write drivers WD2-WD8 of FIG. 5 have the same structure and operation as the first write driver WD1.

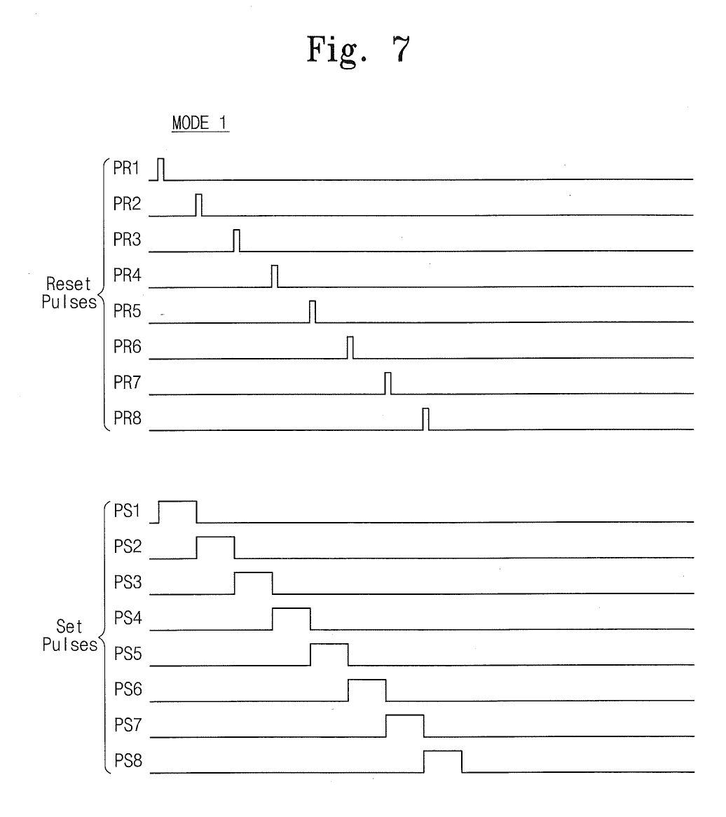

FIGS. 7 to 13 are diagrams illustrating a control method for each mode of set pulses or reset pulses according to the table of FIG. 4.

In the first mode, the reset pulses PR1-PR8 and the set pulses PS1-PS8 are sequentially provided to the write drivers WD1-WD8 of FIG. 5 as illustrated in FIG. 7. Accordingly, the write drivers WD1-WD8 are enabled sequentially one by one.

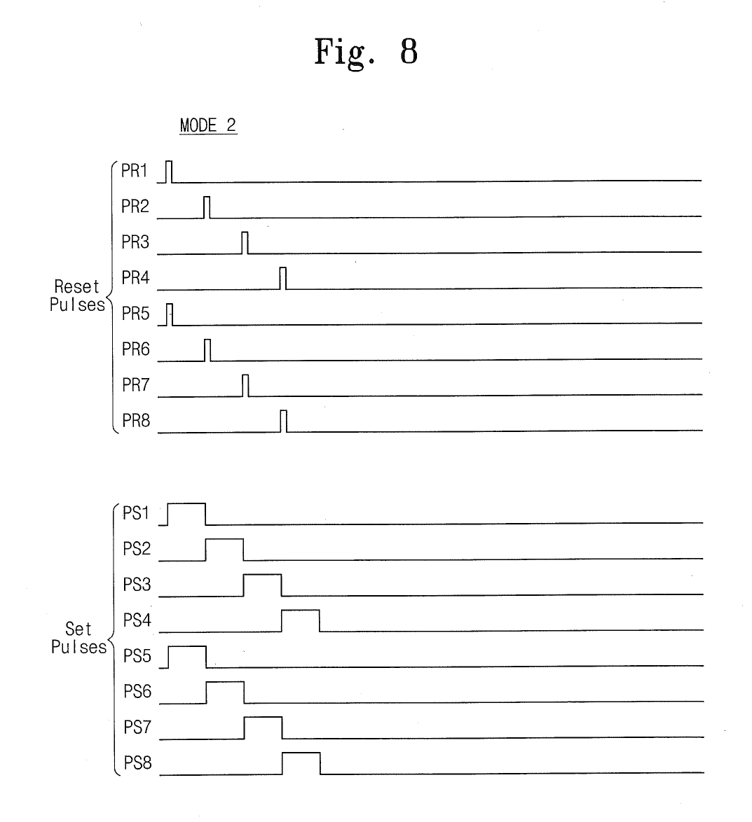

In the second mode, two of the reset pulses PR1-PR8 and two of the set pulses PS1-PS8 are simultaneously provided to the corresponding write drivers as illustrated in FIG. 8. Accordingly, the write drivers WD1-WD8 are enabled sequentially two by two.

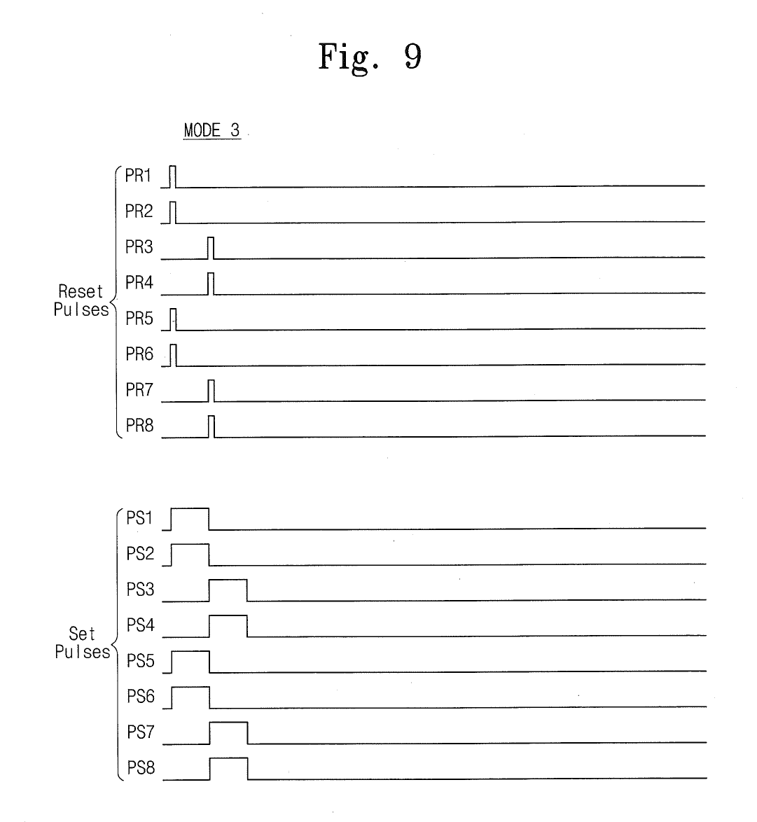

In the third mode, four of the reset pulses PR1-PR8 and four of the set pulses PS1-PS8 are simultaneously provided to the corresponding write drivers as illustrated in FIG. 9. Accordingly, the write drivers WD1-WD8 are enabled sequentially four by four.

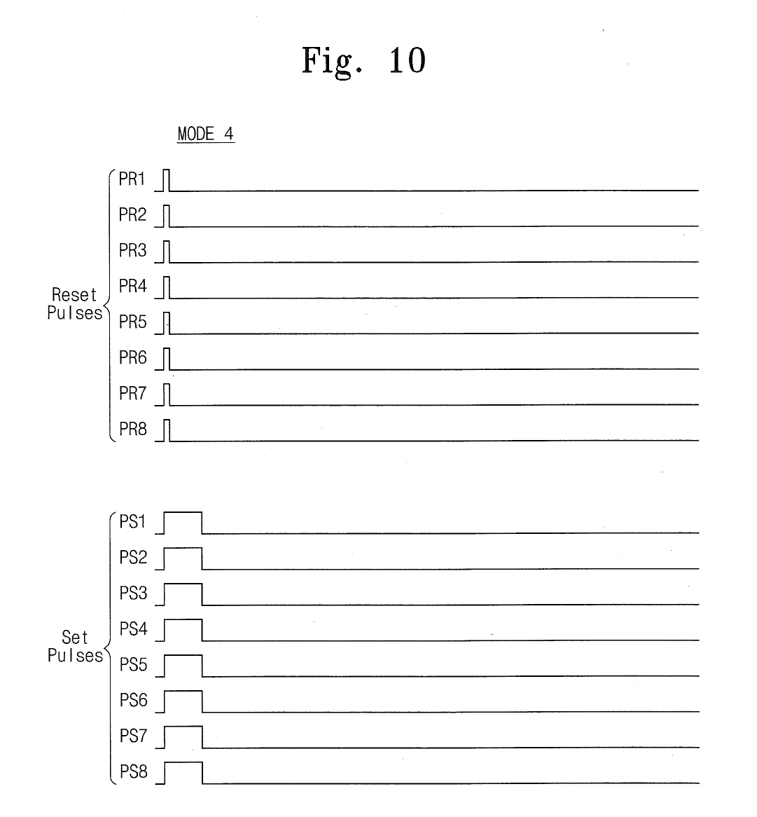

In the fourth mode, the reset pulses PR1-PR8 and the set pulses PS1-PS8 are simultaneously provided to the write drivers WD1-WD8 as illustrated in FIG. 10. Accordingly, the write drivers WD1-WD8 are enabled simultaneously.

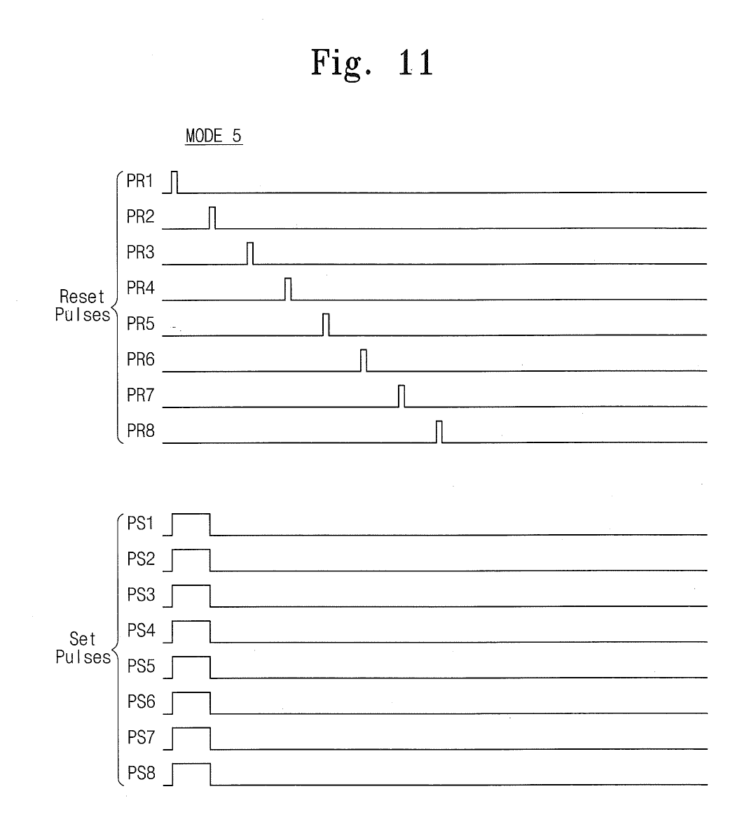

In the fifth mode, as illustrated in FIG. 11, the set pulses PS1-PS8 are simultaneously provided to the write drivers WD1-WD8 and the reset pulses PR1-PR8 and are sequentially provided to the write drivers WD1-WD8. Accordingly, the write drivers WD1-WD8 are enabled simultaneously.

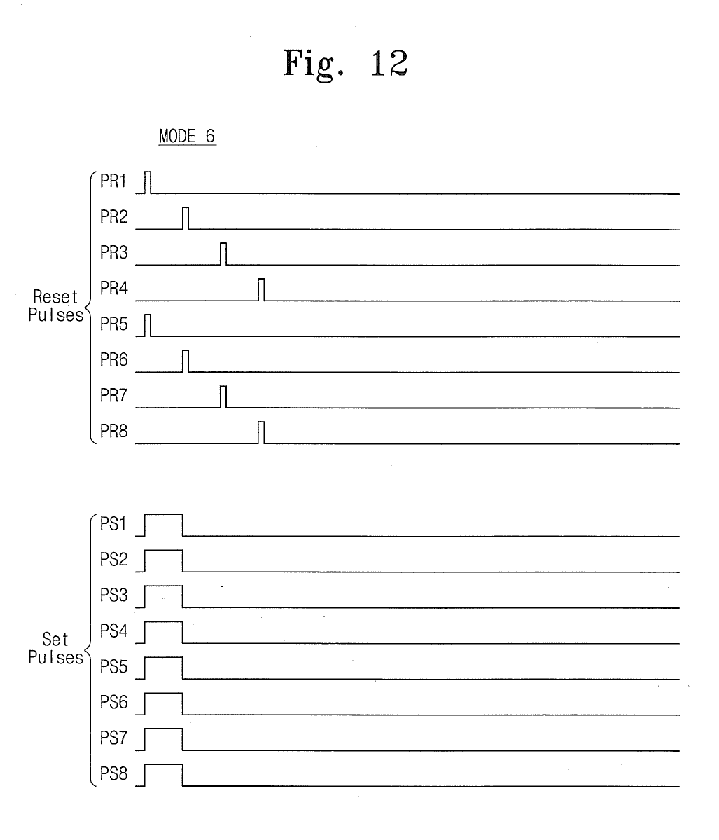

In the sixth mode, as illustrated in FIG. 12, the set pulses PS1-PS8 are simultaneously provided to the write drivers WD1-WD8 and two of the reset pulses PR1-PR8 and are simultaneously provided to the corresponding write drivers. Accordingly, the write drivers WD1-WD8 are enabled simultaneously.

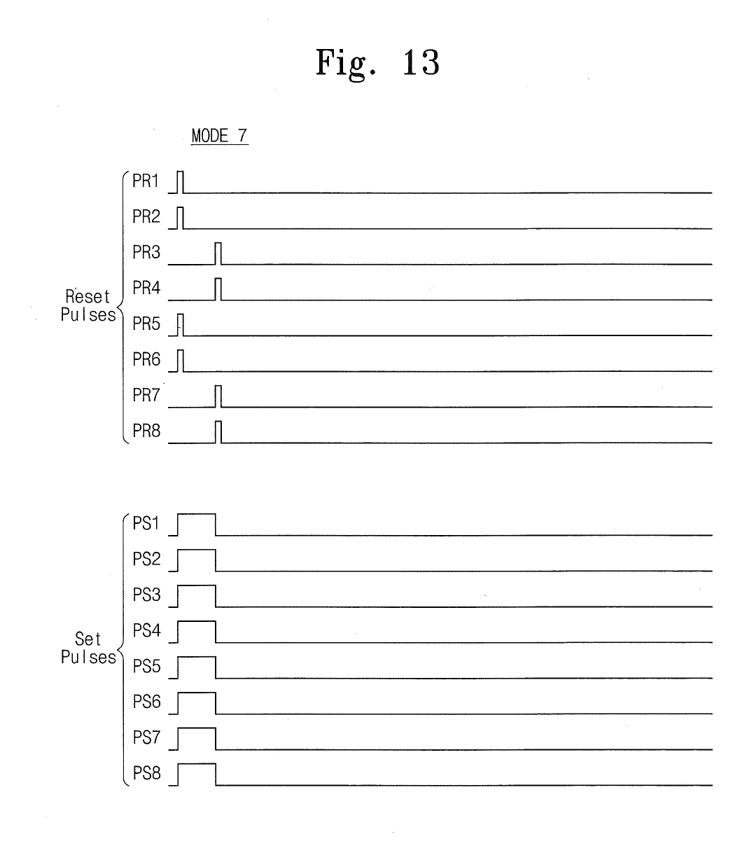

In the seventh mode, as illustrated in FIG. 13, the set pulses PS1-PS8 are simultaneously provided to the write drivers WD1-WD8 and four of the reset pulses PR1-PR8 and are simultaneously provided to the corresponding write drivers. Accordingly, the write drivers WD1-WD8 are enabled simultaneously.

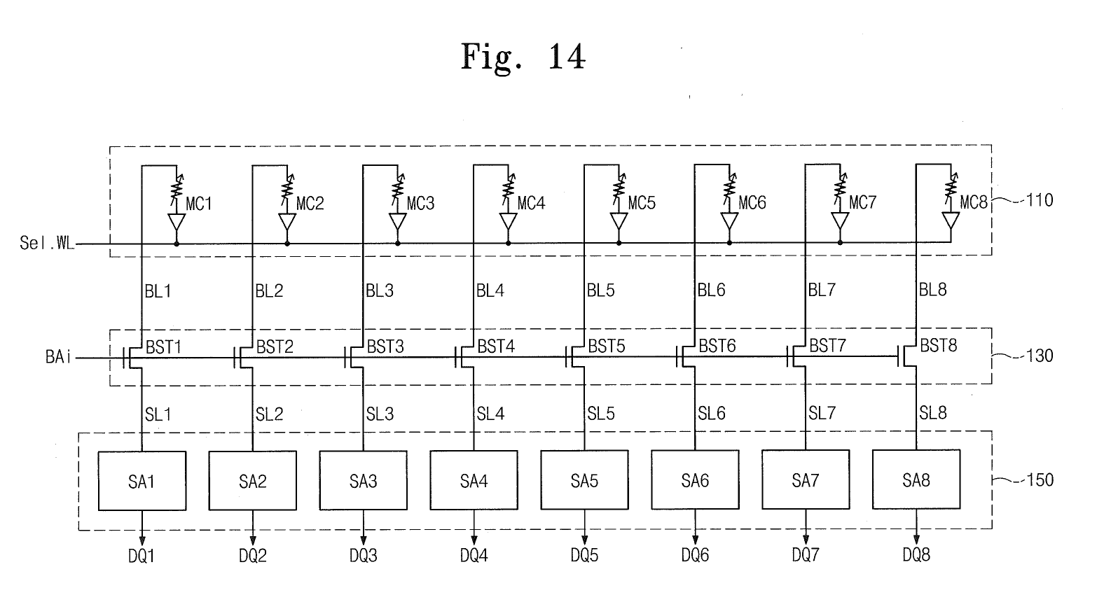

FIG. 14 is a block diagram illustrating a read operation of the nonvolatile memory device of FIG. 2.

Referring to FIG. 14, the memory cells MC1-MC8 are connected to the selected word line Sel. WL. The bit line selection circuit 130 is connected between the bit lines BL1-BL8 and the sensing lines SL1-SL8. The bit line selection circuit 130 electrically connects the sensing lines SL1-SL8 and the selected bit lines BL1-BL8 among the bit lines BL1-BLn of FIG. 2 in response to the bit line selection signal BAi. The bit line selection circuit 130 includes a plurality of units (not illustrated). Each of the select units includes a plurality of transistors BST1-BST8.

The sense amplifier circuit 150 includes a plurality of sense amplifiers SA1-SA8. The sense amplifier circuit 150 provides a read current (or a bias current) through the sensing lines SL1-SL8 to the memory cells MC1-MC8, and compares the voltage of the sensing lines SL1-SL8 with a reference voltage in a sensing operation to read data stored in the memory cell.

In the nonvolatile memory device of FIG. 2, the write mode is set by the manufacturer. However, the nonvolatile memory device of inventive concepts is not limited thereto. The nonvolatile memory device of inventive concepts may set the write mode according to the system environment information sensed by the sensor in the nonvolatile memory device.

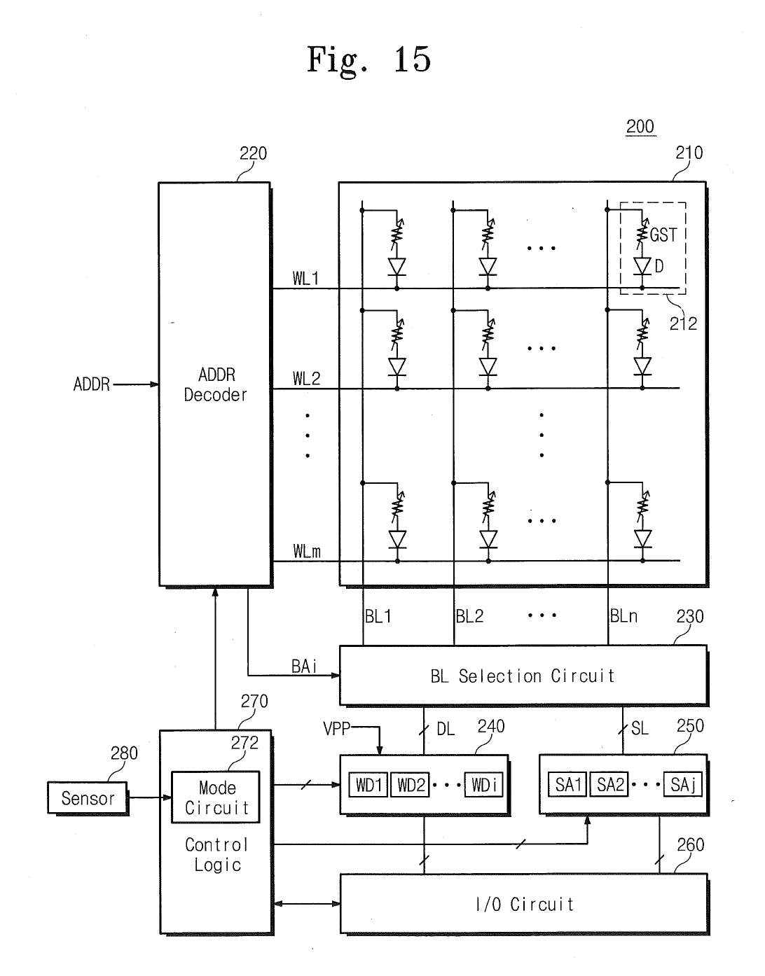

FIG. 15 is a block diagram of a nonvolatile memory device according to another example embodiment of inventive concepts.

Referring to FIG. 15, a nonvolatile memory device 200 includes a memory cell array 210, an address decoder 220, a bit line (BL) selection circuit 230, a write driver circuit 240, a sense amplifier (SA) circuit 250, an input/output (I/O) circuit 260, a control logic 270, and a sensor 280.

The memory cell array 210, the address decoder 220, the bit line selection circuit 230, the write driver circuit 240, the sense amplifier circuit 250 and the input/output circuit 260 have the same structures and operations as the memory cell array 110, the address decoder 120, the bit line selection circuit 130, the write driver circuit 140, the sense amplifier circuit 150 and the input/output circuit 160, respectively, of FIG. 2.

The control logic 270 controls the address decoder 220, the write driver circuit 240, the sensor amplifier circuit 250 and the input/output circuit 260 in response to outputs from the sensor 280. For example, the control logic 270 provides the write driver circuit 240 with a write pulse (e.g., a set pulse or a reset pulse) for generation of write currents in a write operation. Also, the control logic 270 provides the sense amplifier circuit 250 with a read pulse (e.g., a bias signal) for generation of a read current in a read operation.

The control logic 270 includes a mode circuit 272 for setting a write mode. The mode circuit 272 is configured to set one of a plurality of modes. The mode circuit 272 performs a mode setting operation according to the sensing result of the sensor 280. The mode setting operation of the mode circuit 272 may be set by a default value, may be performed in real time during the operation of the nonvolatile memory device 200, or may be performed only when the sensor 280 is enabled. Herein, the sensor 280 may be enabled under the control of the control logic 270 or may be enabled according to the user's selection. For example, the control logic 270 enables the sensor 280 when the write operation count of the memory cell is greater than a predetermined value.

The sensor 280 senses the write environment information of the nonvolatile memory device 200. Herein, the write environment information may be the stability of the voltage level of a high voltage VPP or the temperature of the nonvolatile memory device 200.

In an example embodiment, the sensor 280 senses whether the level of a high-voltage (VPP) pad becomes lower than a predetermined level. As a result of the sensing operation of the sensor 280, if the level of the pad is lower than the predetermined level, it is estimated that stable current supply is difficult in a write operation. According to the sensing result, the mode circuit 272 sets a write mode with appropriate current consumption.

In another example embodiment, the sensor 280 senses whether the temperature of the nonvolatile memory device 200 becomes higher than a predetermined level. As a result of the sensing operation of the sensor 280, if the level of the temperature is higher than the predetermined level, it is estimated that relatively low current consumption is necessary in a write operation. According to the sensing result, the mode circuit 272 sets a write mode with appropriate current consumption.

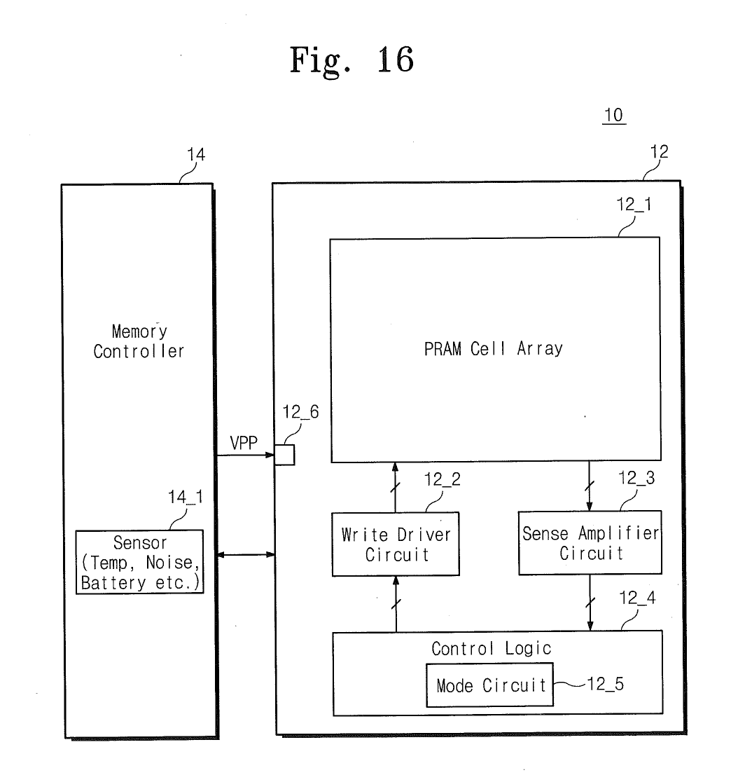

FIG. 16 is a block diagram of a memory system according to an example embodiment of inventive concepts.

Referring to FIG. 16, a memory system 10 includes a nonvolatile memory device 12 and a memory controller 14.

The nonvolatile memory device 12 includes a PRAM cell array 12_1, a write driver circuit 12_2, a sense amplifier circuit 12_3, and a control logic 12_4. The PRAM cell array 12-1 is configured in the same manner as the memory cell array 110 of FIG. 2.

In a write operation, the write driver circuit 122 receives write pulses (e.g., set pulses or reset pulses) form the control logic 12_4, receives data from the memory controller 14, and provides write currents (e.g., set currents or reset currents) to select memory cells. In the write operation, the write driver circuit 12_2 receives a write current through a high voltage VPP. Herein, the high voltage VPP may be provided from the memory controller 14 to a high-voltage pad 12_6.

The sense amplifier circuit 12_3 provides a read current (or a bias current) to select memory cells in a read operation. In the read operation, the sense amplifier circuit 12_3 compares a sensed voltage with a reference voltage to read data stored in the memory cell.

The control logic 12_4 controls the write driver circuit 12_2 and the sensor amplifier circuit 12_3 in response to control signals. For example, the control logic 12_4 provides the write driver circuit 12_2 with a write pulse (e.g., a set pulse or a reset pulse) for generation of write currents in a write operation. Also, the control logic 12_4 provides the sense amplifier circuit 12_3 with a read pulse (e.g., a bias signal) for generation of a read current in a read operation.

The control logic 12_4 includes a mode circuit 12_5 for setting a write mode. The mode circuit 12_5 is configured to set one of a plurality of modes. The mode circuit 12_5 sets a write mode according to the selection of a PRAM mode selector 14_2 in the memory controller 14.

Meanwhile, the nonvolatile memory device 12 may be configured in the same manner as one of the nonvolatile memory device 100 of FIG. 2 and the nonvolatile memory device 200 of FIG. 15.

The memory controller 14 controls the nonvolatile memory device 12 according to a request from an external device (e.g., a host). For example, the memory controller 14 is configured to control a read/write operation of the nonvolatile memory device 12.

The memory controller 14 provides an interface between the nonvolatile memory device 12 and the host. The memory controller 14 is configured to drive a firmware for controlling the nonvolatile memory device 12.

The memory controller 14 includes a sensor 14_1. The sensor 14_1 senses system environment information. Herein, the system environment information may be temperature, noise, battery power, high-voltage level stability, or current capacity.

In an example embodiment, if the system environment information is temperature, the sensor 14_1 includes a temperature sensor that senses the temperature of the memory system 10. In an example embodiment, if the system environment information is noise, the sensor 14_1 includes a sensor unit that senses a noise in a power source. In an example embodiment, if the system environment information is high-voltage level stability, the sensor 14_1 includes a voltage sensor that senses a voltage level change of a line supplied with a high voltage VPP.

In an example embodiment, if the system environment information is current capacity, the sensor 14_1 senses whether a current is consumed more than a predetermined value in the memory controller 14.

According to the sensing result of the sensor 14_1, the mode circuit 12_5 is controlled to set a write mode of the nonvolatile memory device 12. Meanwhile, an operation for selecting one of the write modes may be stored as a firmware in the memory controller 14.

The memory system 10 according to inventive concepts may set a write mode with appropriate current consumption according to the system environment information in a write operation of the nonvolatile memory device 12.

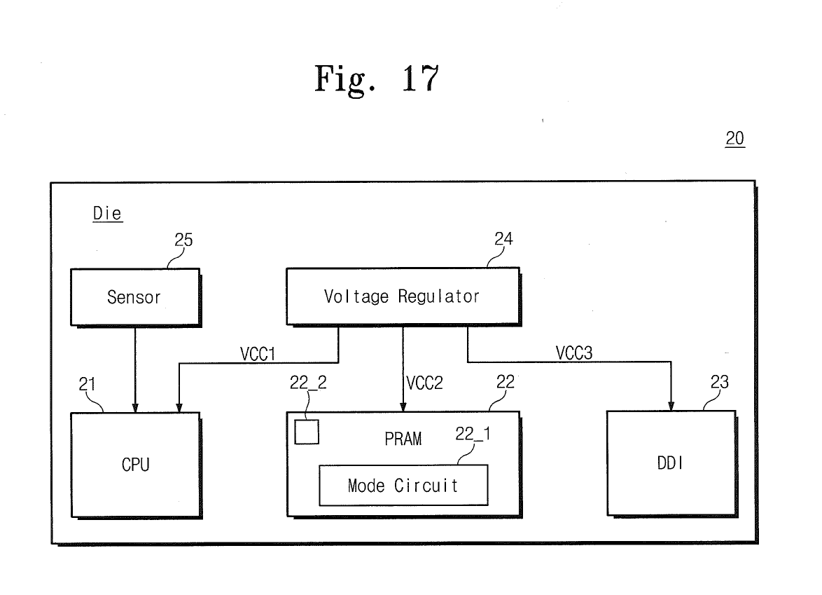

FIG. 17 is a block diagram of an integrated circuit (IC) according to an example embodiment of inventive concepts.

Referring to FIG. 17, an IC 20 includes a central processing unit (CPU) 21, a phase-change RAM (PRAM) 22, a display driver IC (DDI) 23, a voltage regulator 24, and a current sensor 25. The CPU 21, the PRAM 22, the DDI 23, the voltage regulator 24 and the current sensor 25 may be integrated in one die.

The CPU 21 controls an overall operation of the IC 20.

The PRAM 22 stores user data and code values necessary for driving. The PRAM 22 includes a mode circuit 22_1. The PRAM 22 may be configured in the same manner as one of the nonvolatile memory device 100 of FIG. 2, the nonvolatile memory device 200 of FIG. 15 and the nonvolatile memory device 12 of FIG. 16.

The DDI 23 is a driving chip for driving a display. Examples of the display include LCD (Liquid Crystal Display), FPD (Flat Panel Display), Plasma Display Panel (PDP), and OLED (Organic Light Emitting Diode).

The voltage regulator 24 generates voltages VCC1, VCC2 and VCC3 necessary to drive the internal device 21, 22 and 23 of the IC 20.

The sensor 25 senses the environment information of the IC 20. Herein, the environment information of the IC 20 may be temperature, voltage level, current capacity, or battery power.

For example, the sensor 25 senses the amount of currents used by the internal devices 21, 22 and 23 of the IC 20. According to the sensed current amount, the CPU 21 sets a write mode of the PRAM 22 so that the total current amount does not exceed a predetermined value. For example, if the limit capacity of the IC 20 is about 500 mA and the CPU 21 and the DDI 23 consumes a current of about 400 mA, the CPU 21 controls the mode circuit 22_1 of the PRAM 22 to set a write mode with a current consumption of up to about 100 mA.

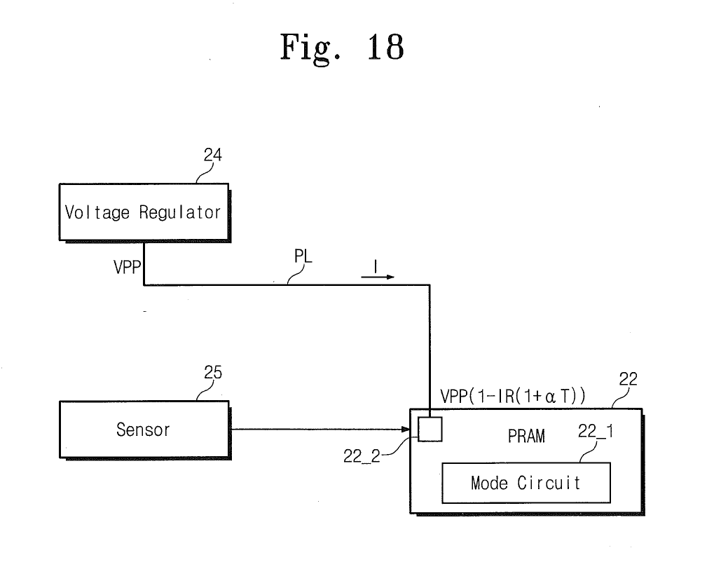

FIG. 18 is a diagram illustrating a method of setting a write mode according to the current capacity provided to the PRAM 22 from the IC 20 illustrated in FIG. 17.

Referring to FIG. 18, if the environment information of the IC 20 is the current capacity provided to the PRAM 22, the sensor 25 senses the voltage of a voltage pad 22_2 receiving a high voltage VPP. An internal resistance value of a power line PL between the voltage regulator 24 and the PRAM 22 becomes IR(1+αT). Herein, I is the current supplied from the voltage regulator 24 to the PRAM 22, R is a resistance value at room temperature, α is a temperature coefficient, and T is the temperature of the IC 10. Thus, the resistance value of the power line PL increases as the temperature T of the IC 20 increases. Accordingly, the voltage of the voltage pad of the PRAM 22 becomes VPP(1−IR(1+αT)).

The sensor 25 senses the voltage of the voltage pad of the PRAM 22. The sensed voltage value is transmitted from the CPU 21. The CPU 21 determines whether to reset a write mode of the PRAM 22 according to the sensed pad voltage. For example, if the temperature T of the IC 21 rapidly increases and the voltage of the voltage pad 22_2 rapidly decreases, the CPU 21 determines that a smooth write current I cannot be provided to the PRAM 22. Accordingly, the CPU 21 controls the mode circuit 22_1 to reset a write mode of the PRAM 22.

The write current control method of the nonvolatile memory device according to inventive concepts has been described above with reference to FIGS. 1 to 18. However, inventive concepts are not limited to a write current control. Inventive concepts may control the peak current of the nonvolatile memory device.

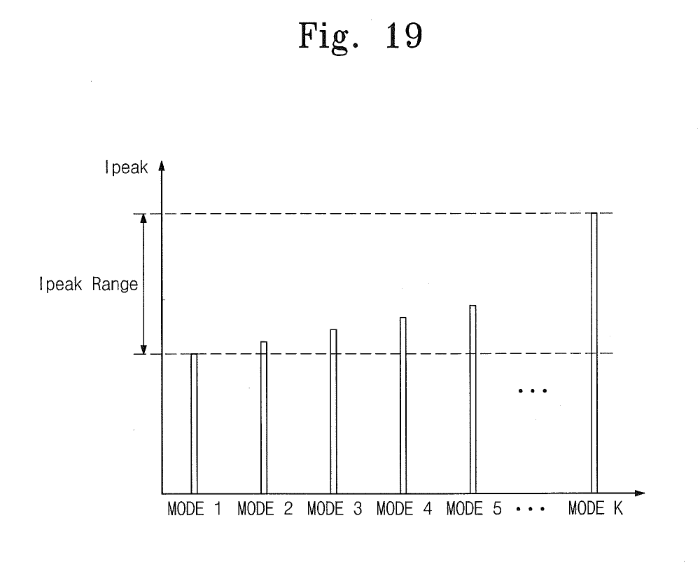

FIG. 19 is a diagram illustrating a peak current corresponding to each mode of a nonvolatile memory device according to an example embodiment of inventive concepts.

Referring to FIG. 19, a nonvolatile memory device according to an example embodiment of inventive concepts has a peak current range. Herein, the peak current range means the range of a peak current allowable by the nonvolatile memory device. The peak current of the nonvolatile memory device varies according to each mode. For example, the first mode has the lowest peak current level. On the other hand, the K^{th} mode (k: a natural number) has the highest peak current level.

The nonvolatile memory device according to inventive concepts varies the peak current value according to the set mode. The peak current value of the nonvolatile memory device depends on the amount of simultaneously-provided write currents (e.g., reset currents or set currents) in a write operation. For example, the peak current value increases when the amount of simultaneously-provided write currents is large.

The PRAM according to inventive concepts is applicable to a memory module.

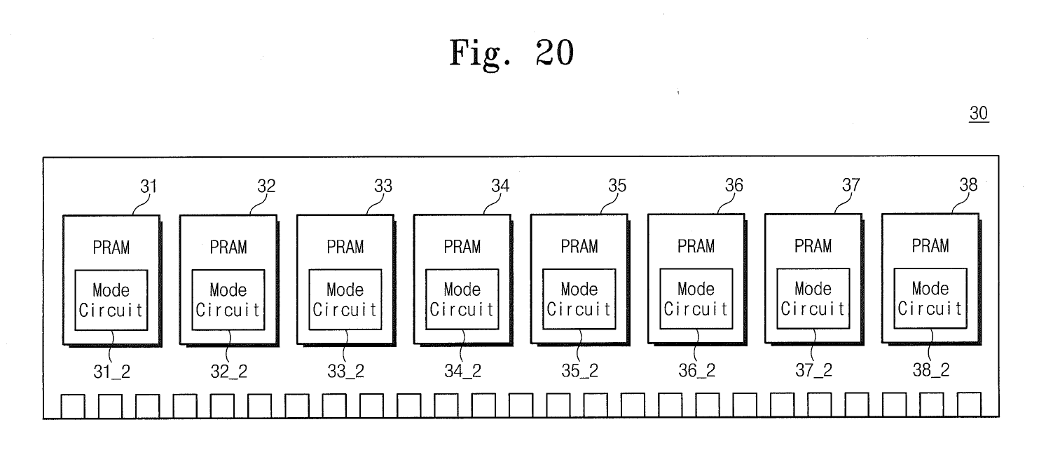

FIG. 20 is a block diagram of a memory module according to an example embodiment of inventive concepts.

Referring to FIG. 20, a memory module 30 includes a plurality of PRAM devices 31-38. Each of the PRAM devices 31-38 may be configured in the same manner as one of the nonvolatile memory device 100 of FIG. 2, the nonvolatile memory device 200 of FIG. 15 and the nonvolatile memory device 12 of FIG. 16.

The PRAM devices 31-38 include mode circuits 31_2-38_2, respectively, that can set a write mode according to estimated appropriate current consumption. A manufacturer of the memory module 30 sets a write mode of the mode circuit 31_2-38_2 according to the current consumption of an overall system using the memory module 30.

FIG. 20 illustrates that the memory module 30 includes eight PRAM devices. However, the memory module of inventive concepts is not limited thereto. The memory module of inventive concepts may include at least one PRAM device.

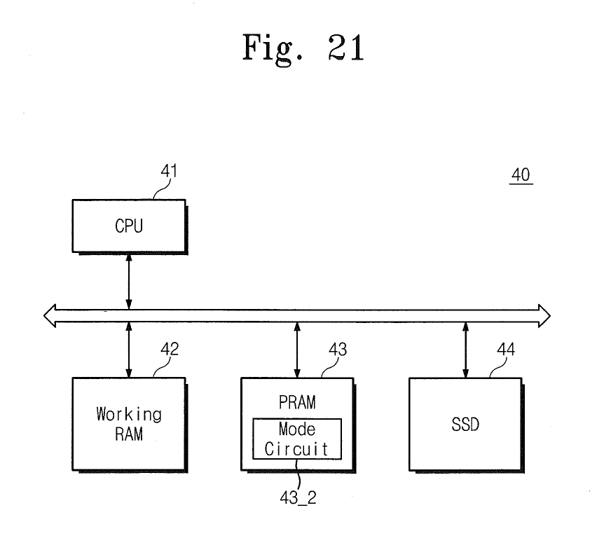

FIG. 21 is a block diagram of a memory system according to another example embodiment of inventive concepts.

Referring to FIG. 21, a memory system 40 includes a central processing unit (CPU) 41, a working RAM 42, a phase-change RAM (PRAM) device 43, and a solid state drive (SSD) 44.

The CPU 41 controls an overall operation of the memory system 40.

The working RAM 42 temporarily stores data required in an operation of the CPU 41. The working RAM 42 may be configured using a DRAM, an SRAM or an M-SDRAM.

The PRAM device 43 stores boot code/data of the memory system 40. A booting operation is performed according to the stored boot code/data. The PRAM device 43 may be configured in the same manner as one of the nonvolatile memory device 100 of FIG. 2, the nonvolatile memory device 200 of FIG. 15 and the nonvolatile memory device 12 of FIG. 16. The PRAM device 43 includes a mode circuit 43_2 that is configured to set a write mode according to estimated appropriate current consumption.

The SSD 44 includes one or more flash memories (not illustrated) and a memory controller (not illustrated) that is configured to control the flash memories. Each of the flash memories is configured to store user data.

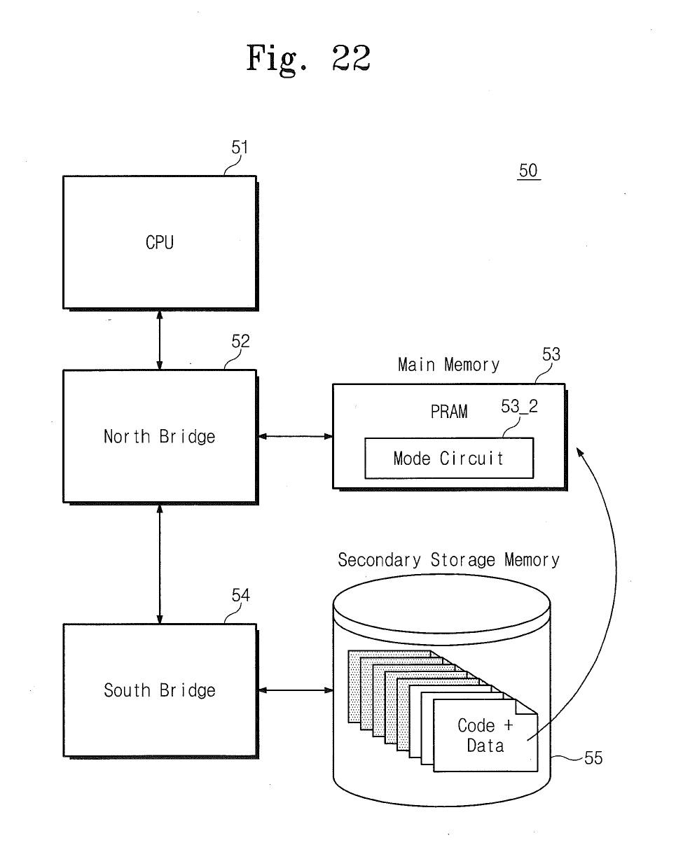

FIG. 22 is a block diagram of a computing system according to an example embodiment of inventive concepts.

Referring to FIG. 22, a computing system 50 includes a central processing unit (CPU) 51, a north bridge 52, a phase-change RAM (PRAM) device 53, a south bridge 54, and a storage device 55. The PRAM device 53 is configured to store the code/data of an application program and the boot code/data of an operating system capable of Execution In Place (XIP). Herein, the XIP means execution that is performed directly without transferring to a system memory. Herein, the data stored in the PRAM device 53 may be application code/data and operating system boot code/data that are loaded from the storage device 55.

The PRAM device 53 may be configured in the same manner as one of the nonvolatile memory device 100 of FIG. 2, the nonvolatile memory device 200 of FIG. 15 and the nonvolatile memory device 12 of FIG. 16. The PRAM device 53 includes a mode circuit 53_2 that is configured to set a write mode according to estimated appropriate current consumption.

The CPU 51 controls an overall operation of the computing system 50.

The north bridge 52 is connected to the CPU 51. The north bridge 52 may be a hardware or software module for connecting peripheral devices or system components that require high data rate and system performance.

The PRAM device 53 is configured to store application code/data, boot code/data of an operating system, and data used to perform an operation of the CPU 51.

The south bridge 54 is connected to the north bridge 52. The south bridge 54 may be a hardware or software module for connecting peripheral devices or system components that require low data rate and system performance.

The storage device 55 is connected to the south bridge 54 to store user data. An application program and an operating system of the computing system 50 are installed in the storage device 55. That is, the storage device 55 stores application code/data or boot code/data of the operating system. The storage device 55 may be a flash memory storage device, a hard disk driver (HDD) or a solid state drive (SSD).

In the computing system 50 according to inventive concepts, the nonvolatile XIP characteristics of the PRAM device 53 are used to greatly reduce the booting time, the application launching time, and the hibernation on/off time. Accordingly, the power consumption of the computing system 50 can be greatly reduced.

The computing system 50 according to inventive concepts includes a mode circuit 53_2 that is configured to set a write mode according to estimated appropriate current consumption. Accordingly, an write operation of the PRAM device 53 can be performed with appropriate current consumption on the system level. Consequently, it is possible to implement a stable system operation of the computing system 50.

The memory system or the storage device according to inventive concepts may be used as a mobile storage device. Thus, the memory system or the storage device according to inventive concepts may be used as a storage device for MP3 players, digital cameras, PDAs or e-books. Also, the memory system or the storage device according to inventive concepts may be used as a storage device for digital TVs or computers.

The memory system or the storage device according to inventive concepts may be mounted in various types of packages. Examples of the packages of the memory system or the storage device according to inventive concepts include Package on Package (PoP), Ball Grid Arrays (BGAs), Chip Scale Packages (CSPs), Plastic Leaded Chip Carrier (PLCC), Plastic Dual In-line Package (PDIP), Die in Waffle Pack, Die in Wafer Form, Chip On Board (COB), Ceramic Dual In-line Package (CERDIP), Plastic Metric Quad Flat Pack (MQFP), Thin Quad Flat Pack (TQFP), Small Outline Integrated Circuit (SOIC), Shrink Small Outline Package (SSOP), Thin Small Outline Package (TSOP), System In Package (SIP), Multi Chip Package (MCP), Wafer-level Fabricated Package (WFP), and Wafer-level Processed Stack Package (WSP).

The above-disclosed subject matter is to be considered illustrative and not restrictive, and the appended claims are intended to cover all such modifications, enhancements, and other embodiments, which fall within the true spirit and scope of inventive concepts. Thus, to the maximum extent allowed by law, the scope of inventive concepts is to be determined by the broadest permissible interpretation of the following claims and their equivalents, and shall not be restricted or limited by the foregoing detailed description.

What is claimed is:

1. A memory system comprising:
a nonvolatile memory device having a plurality of write modes; and
a memory controller including a sensor configured to sense environment information of the memory system, the memory controller being configured to select one of the plurality of write modes according to the sensed environment information, and control the nonvolatile memory device according to the selected write mode.

2. The memory system of claim 1, wherein the nonvolatile memory device is configured to apply at least one of a number of applied set pulses associated with the selected write mode and a number of applied reset pulses associated with the selected write mode in a write operation.

3. The memory system of claim 1, wherein the nonvolatile memory device comprises a mode circuit configured to set one of the write modes.

4. The memory system of claim 1, wherein
the memory controller is configured to provide a high voltage to a high-voltage pad of the nonvolatile memory device in a write operation,
the sensor is configured to sense, as environment information, a decrease of the high voltage provided to the high-voltage pad.

5. The memory system of claim 1, wherein the environment information includes at least one of temperature, current capacity, high-voltage level, and battery capacity.

6. The memory system of claim 5, wherein, if the environment information is current capacity, the sensor is configured to sense the current capacities used by the memory system and the memory controller is configured to select one of the write modes according to the sensed current capacities.

7. The memory system of claim 1, wherein the nonvolatile memory device is a phase-change memory device.

8. The memory system of claim 1, wherein a peak current value of the nonvolatile memory device varies according to the selected write mode.

9. A method of controlling write currents of a nonvolatile memory device, comprising:
estimating a current consumption of the nonvolatile memory device;
setting a write mode according to the estimated current consumption; and
controlling an amount of write currents applied to the nonvolatile memory device in a write operation according to the set write mode.

10. The method of claim 9, wherein the estimating estimates the current consumption of the nonvolatile memory device according to the application of the nonvolatile memory device.

11. The method of claim 9, wherein the estimating is performed in the nonvolatile memory device.

12. The method of claim 9, wherein the estimating is performed in the nonvolatile memory device.

13. The method of claim 9, wherein the setting selects the write mode from a plurality of modes, each of the modes corresponds to a number of enabled write drivers.

14. The method of claim 9, wherein the setting selects the write mode from a plurality of modes, each of the modes corresponds to at least one of a number of set pulses and a number of reset pulses to apply to the nonvolatile memory device.

15. A nonvolatile memory device comprising:
a memory cell array including a plurality of variable-resistance cells;
a write driver circuit configured to provide write currents to the variable-resistance cells selected in response to received set pulses or received reset pulses; and
a control logic configured to generate the set pulses or the reset pulses in the write operation and determine at least one of a number of the reset pulses and a number of the set pulses according to the set write mode.

16. The nonvolatile memory device of claim 15, wherein the write driver circuit is configured to receive a high voltage from an external device in a write operation.

17. The nonvolatile memory device of claim 15, the control logic comprises a mode circuit configured to set the write mode according to estimated current consumption.

18. The nonvolatile memory device of claim 17, further comprising:
a sensor configured to sense the current consumption.

19. The nonvolatile memory device of claim 17, wherein the mode circuit is configured to set the write mode by fuse cutting.

20. The nonvolatile memory device of claim 17, wherein the mode circuit is configured to set the write mode by register setting.
